(19) United States
(12) Patent Application Publication
(10) Pub. No.: US 2024/0175115 A1
(43) Pub. Date: May 30, 2024

(54) DEPOSITION MASK

(71) Applicant: Samsung Display Co., LTD., Yongin-si (KR)

(72) Inventors: SEUNGPYO HONG, Yongin-si (KR); DONGJIN HA, Yongin-si (KR)

(73) Assignee: Samsung Display Co., LTD., Yongin-si (KR)

(21) Appl. No.: 18/466,941

(22) Filed: Sep. 14, 2023

(30) Foreign Application Priority Data
Nov. 30, 2022 (KR) 10-2022-0164315

(51) Int. Cl. C23C 14/04; C23C 14/24

(52) U.S. Cl. CPC C23C 14/042; C23C 14/24; H10K 59/10

(57) ABSTRACT

A deposition mask for forming a pattern on a substrate to be deposited, includes a first portion having an upper surface, a second portion having an upper surface half-etched to a first depth from the upper surface of the first portion, and a third portion having an upper surface half-etched to a second depth from the upper surface of the second portion. The third portion defines an opening corresponding to the pattern, and an upper surface of the third portion includes a plane perpendicular to a thickness direction of the deposition mask.

### CROSS-REFERENCE TO RELATED APPLICATION(S)

This application claims priority to and the benefit of Korean Patent Application No. 10-2022-0164315 filed in the Korean Intellectual Property Office on Nov. 30, 2022, the entire contents of which are incorporated herein by reference.

### BACKGROUND

### 1. Technical Field

This disclosure relates to a deposition mask that may be used in manufacturing a display device.

### 2. Description of the Related Art

A deposition mask (or mask for deposition) may be used in manufacturing electronic devices such as display devices. For example, the deposition mask may be used in a deposition process for forming a common layer on a substrate of a display device including an organic light emitting diode (OLED). The substrate on which the common layers will be formed may be aligned on the deposition mask, a material of the common layers may pass through openings of the deposition mask, and common layers corresponding to the openings of the deposition mask may be deposited on the substrate.

Recently, display devices for metaverses such as augmented reality, virtual reality, and a mixed reality are being put into practical use. Display devices for the metaverse (or a display device for glasses) requires high resolution while being small. To this end, a display device with an OLEDoS (OLED on Silicon) structure in which an OLED is deposited on a silicon wafer instead of a glass substrate or a plastic substrate used as a substrate for a conventional display device is being developed. These display devices are also referred to as a micro OLED, and may implement an ultra-high-resolution display device with a pixel size of tens of micrometers or less.

Material of common layers may be vaporized from a deposition source and emitted from a nozzle to pass through openings of a deposition mask. At this time, particles of the material may be deposited on a substrate with a certain angle while moving in a straight line at the radiated angle. A portion (i.e., a portion with a non-uniform thickness) where particles are not evenly (e.g., with a uniform thickness) deposited on the substrate may occur due to the angle of incidence of the particles passing through the openings of the mask. This region is referred to as a shadow.

In case depositing the common layer of the display device, shadows may be generated by the cross-sectional shape of the mask and the incidence angle from the deposition source. Reducing the shadow may be effective in reducing a dead space as well as in increasing position accuracy.

The above information disclosed in this Background section is only for enhancement of understanding of the background, and therefore it may contain information that does not form the prior art that is already known in this country to a person of ordinary skill in the art.

### SUMMARY

Embodiments provide a deposition mask capable of reducing shadow.

A deposition mask for forming a pattern on a substrate to be deposited is provided. The deposition mask may include a first portion having an upper surface, a second portion having an upper surface half-etched to a first depth from the upper surface of the first portion, and a third portion having an upper surface half-etched to a second depth from the upper surface of the second portion. The third portion may define an opening corresponding to the pattern, and an upper surface of the third portion may include a plane perpendicular to a thickness direction of the deposition mask.

The upper surface of the first portion and the upper surface of the second portion may each include a plane perpendicular to the thickness direction of the deposition mask.

The first portion may have a first thickness, the second portion may have a second thickness smaller than the first thickness, and the third portion may have a third thickness smaller than the second thickness.

The second portion may be disposed between the first portion and the second portion.

The third portion may have a tapered shape in which a thickness is thinner toward the opening.

The third portion may have an edge parallel to the thickness direction of the mask.

In case the substrate and the deposition mask are combined, the upper surface of the second portion may be in physical contact with the substrate and the upper surface of the third portion may be spaced apart from the substrate.

The deposition mask may further include at least one groove half-etched from a lower surface of the deposition mask.

The at least one groove may include a first groove disposed in the first portion and a second groove disposed in at least one of the second portion and the third portion.

The first portion may surround the second portion, and a boundary between the first portion and the second portion may be circular in plan view.

A deposition mask for forming a pattern on a substrate to be deposited may include a first portion having a first thickness, a second portion having a second thickness smaller than the first thickness, and a third portion having a third thickness smaller than the second thickness. In case the substrate and the deposition mask are combined, an upper surface of the second portion may be in physical contact with a lower surface of the substrate and an upper surface of the third portion may be spaced apart from the lower surface of the substrate.

The substrate may be fixed to a carrier, and in case the substrate and the deposition mask are combined, an upper surface of the first portion may be in physical contact with the carrier.

The second portion and the third portion may be half-etched at different depths from an upper surface of the first portion of the deposition mask.

The second portion may be half-etched from the upper surface of the first portion with a depth in a range of about 5 μm to about 60 μm, and the third portion may be half-etched from the upper surface of the second portion with a depth in a range of about 5 μm to about 40 μm.

The deposition mask may further include at least one groove half-etched from a second surface of the deposition mask.

The second portion may be disposed between the first portion and the third portion, and the third portion may define an opening corresponding to the pattern.

The third portion may have a tapered shape in which a thickness is thinner toward the opening.

The third portion may have an edge parallel to the thickness direction of the mask.

The deposition mask may further include an opening defined by the second portion and an opening defined by the third portion.

The first portion may surround the second portion, and a boundary between the first portion and the second portion may be circular in plan view.

According to embodiments, a deposition mask capable of preventing damage to the substrate and reducing a shadow may be provided. According to the embodiments, it may be possible to prevent the deposition mask from being rolled up. According to the embodiments, there are advantageous effects that may be recognized throughout the specification.

### BRIEF DESCRIPTION OF THE DRAWINGS

FIG. 1 is a schematic view of a deposition device according to an embodiment.

FIG. 2A and FIG. 2B are a schematic perspective view and a schematic top plan view of a deposition mask according to an embodiment, respectively, and FIG. 2C is a schematic cross-sectional view taken along line A-A′ of FIG. 2A.

FIG. 3A and FIG. 3B are schematic cross-sectional views of states before and after coupling a deposition mask and a substrate according to an embodiment, respectively.

FIG. 4A and FIG. 4B are schematic cross-sectional views of states before and after coupling a deposition mask and a substrate according to a comparative example, respectively.

FIG. 5 is a schematic cross-sectional view of a portion of a deposition mask according to an embodiment.

FIG. 6A is a schematic top plan view of a deposition mask according to an embodiment, FIG. 6B is a schematic cross-sectional view taken along line A-A′ of FIG. 6A, and FIG. 6C is a schematic cross-sectional view taken along line B-B′ of FIG. 6A.

FIG. 7A is a schematic top plan view of a deposition mask according to an embodiment, FIG. 7B is a schematic cross-sectional view taken along line A-A′ of FIG. 7A, and FIG. 7C is a schematic cross-sectional view taken along line B-B′ of FIG. 7A.

FIG. 8 is a schematic cross-sectional view of a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

In the drawings, sizes, thicknesses, ratios, and dimensions of the elements may be exaggerated for ease of description and for clarity. Like numbers refer to like elements throughout.

It will be understood that when an element such as a layer, film, region, or substrate is referred to as being “on” another element, it can be directly on the other element or intervening elements may also be present. In contrast, when an element is referred to as being “directly on” another element, there may be no intervening elements present.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Throughout the specification, “connected” does not only mean that two or more constituent elements are directly connected, but when two or more constituent elements are connected indirectly through other constituent elements, and it may include a case where substantially integral parts are connected to each other even if they may be referred to by a different name depending on the position or function.

It will be understood that the terms “connected to” or “coupled to” may include a physical and/or electrical connection or coupling.

In the drawings, symbols “x”, “y”, and “z” representing directions are used. Here “x” may be a first direction, “y” may be a second direction perpendicular to the first direction, and “z” may be a third direction perpendicular to the first direction and the second direction.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

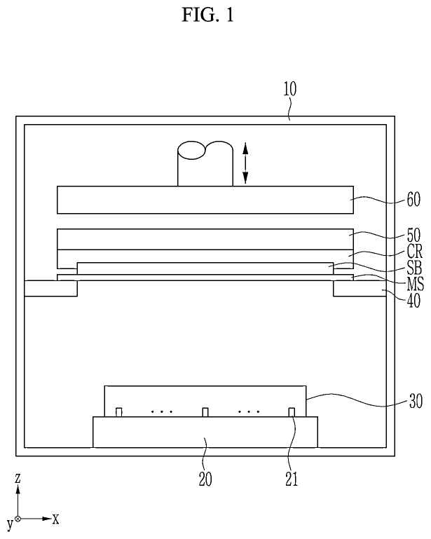

FIG. 1 is a schematic view of a deposition device according to an embodiment.

Referring to FIG. 1, a deposition device according to an embodiment may include a chamber 10, a deposition source 20, a deposition angle limiting unit 30, a holder 40, a cool plate 50, and a magnet assembly 60. The deposition source 20, the holder 40, the cool plate 50, and the magnet assembly 60 may be disposed in the chamber 10.

The chamber 10 may be a vacuum chamber, and the inside of the chamber 10 may be maintained in a vacuum atmosphere or an inert gas atmosphere such as with nitrogen gas. The chamber 10 may be connected to a vacuum pump (not shown) to control the pressure inside. Depositing the deposition material on the substrate SB for manufacturing the display devices and the like may be performed within the chamber 10 of this deposition device. The substrate SB may be a wafer substrate. One substrate SB may be used to fabricate multiple display devices. The substrate SB may be fixed by a carrier CR inside the chamber 10. Below the substrate SB, a deposition mask MS (hereinafter referred to simply as “mask”) for the deposition may be disposed. The mask MS may be configured to be detachable/attachable to the holder 40 above the deposition source 20. The mask MS may be a metal mask having an opening corresponding to a pattern to be formed on the substrate SB. By disposing the mask MS between the deposition source 20 and the substrate SB, the deposition material may be deposited in a predetermined or selected pattern on the substrate SB. The chamber 10 may include an inlet (not shown) for carrying the substrate SB, the carrier CR, and the mask MS in and out.

The deposition source 20 may store and evaporate a deposition material (e.g., an emission layer material of a light emitting display device). The deposition source 20 may spray the deposition material toward the substrate SB, which is the deposition target. The deposition source 20 may be a linear deposition source. The deposition source 20 may have a length in the first direction x and a width in the second direction y, and the length may be greater than the width. The deposition source 20 may include nozzles 21 emitting material particles. The nozzles 21 may be arranged in a row or multiple rows along the first direction x on the deposition source 20. The deposition source 20 may be a point deposition source.

The deposition angle limiting unit 30 may be disposed on the deposition source 20. The deposition angle limiting unit 30 may make the incidence angle of the particles emitted from the nozzles 21 and directed to the substrate SB through the opening of the mask MS greater than a predetermined or selected angle. Accordingly, the shadow region may be reduced and the deposition quality may be improved.

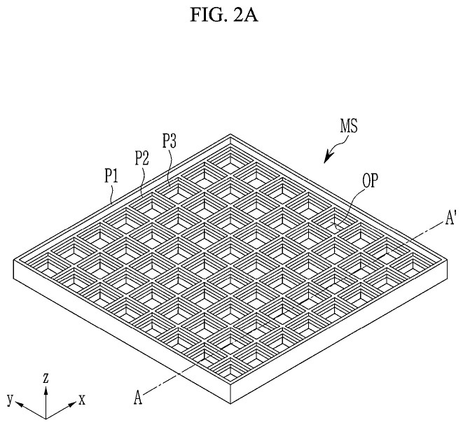

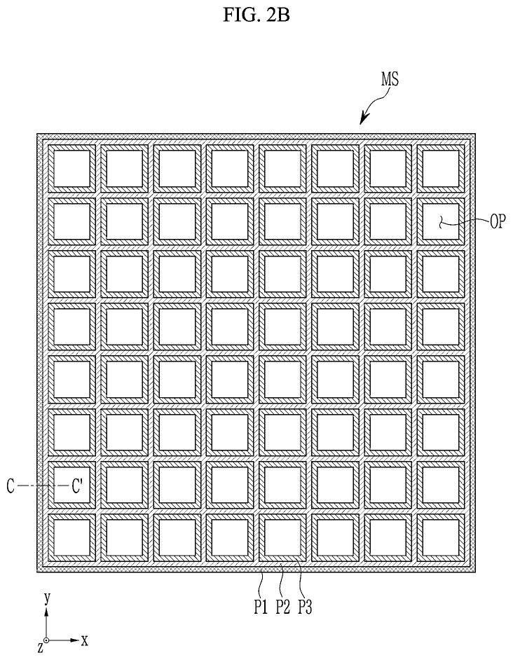

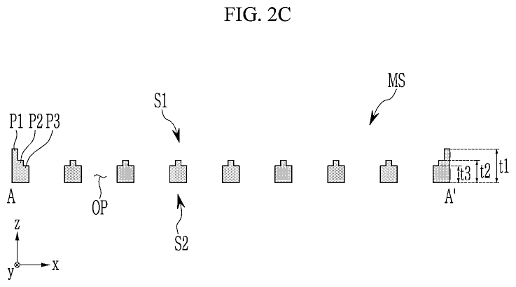

FIG. 2A and FIG. 2B are a schematic perspective view and a schematic top plan view of a deposition mask according to an embodiment, respectively, and FIG. 2C is a schematic cross-sectional view taken along line A-A′ of FIG. 2A.

Referring to FIG. 2A, FIG. 2B, and FIG. 2C, a deposition mask MS may have a three-dimensional shape of an approximate hexahedron and a flat shape of an approximate quadrangle with a predetermined or selected thickness as a whole. The mask MS may include a first surface (S1, an upper surface) facing the substrate SB in the chamber 10 and a second surface (S2, a lower surface) facing the deposition source 20. The mask MS may include openings OP formed by penetrating the mask MS in a third direction z that is a thickness direction. The opening OP may have a shape corresponding to the pattern to be deposited (e.g., a common layer of a display device), and for example, may have a planar shape of an approximate quadrangle. The opening OP may have various shapes in plan view corresponding to the pattern to be deposited, such as a polygon, a circle, and an ellipse other than a quadrangle. The mask MS may be formed of a metal or an alloy, for example, an alloy such as Invar and stainless steel.

The mask MS may include a first portion P1 with a first thickness t1, a second portion P2 with a second thickness t2, and a third portion P3 with a third thickness t3. In FIG. 2A, different shades are given to the first portion P1, the second portion P2, and the third portion P3 so as to distinguish the first portion P1, the second portion P2, and the third portion P3. The first portion P1 may correspond to the edge of the mask MS. The first portion P1 may have an approximate quadrangular planar shape. The second portion P2 may have a planar shape of a mesh form. The third portion P3 may define an opening OP. The third portion P3 may include sections separated from each other, and each section may define one opening OP. Each section may have a planar shape of an approximate quadrangle in a plan view, but may have various planar shapes such as a polygon, a circle, and an ellipse other than a quadrangle. The spacing between the sections may be the same, but in other embodiments may be different.

The first portion P1, the second portion P2, and the third portion P3 may be different only in height, and may be integral with each other. The mask MS may be formed by etching a single metal plate. The first portion P1 may correspond to the portion of the metal plate that is not etched, and the second portion P2 may correspond to the portion of the metal plate half-etched from the first surface S1 of the metal plate to a depth corresponding to a difference (t1−t2) between the first thickness t1 and the second thickness t2, and the third portion P3 may correspond to the portion of the metal plate that is half-etched from the first surface S1 of the metal plate to a depth corresponding to the difference (t1−t3) between the first thickness t1 and the third thickness t3. The opening OP may be a region etched from the first surface S1 of the metal plate to a depth corresponding to the first thickness t1 (i.e., a depth penetrating the metal plate).

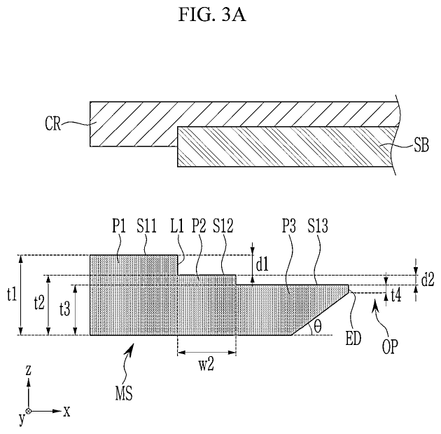

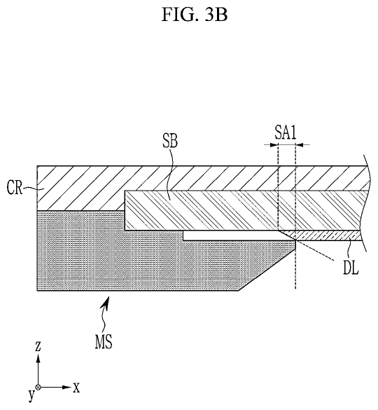

FIG. 3A and FIG. 3B are schematic cross-sectional views of states before and after coupling a deposition mask and a substrate according to an embodiment, respectively.

The mask MS shown in FIG. 3A and FIG. 3B may correspond to the cross-section taken along line C-C′ in FIG. 2B. The substrate SB, which may be a wafer, may be fixed to the carrier CR. The substrate SB may be protruded downward from the carrier CR. For example, in case that the substrate SB and the carrier CR are combined, the substrate SB may be protruded in a range of about 0 μm to about 80 μm downward from the lower surface of the carrier CR. In order to prevent interference with the protruded substrate SB in case combining the mask MS, the mask MS may have a stepped structure. For example, the mask MS may include the first portion P1 of the first thickness t1 and the second portion P2 of the second thickness t2 positioned adjacently, and the second portion P2 may accommodate the protruded portion of the substrate SB.

The first portion P1 may be disposed without overlapping the substrate SB. The second portion P2 may be disposed to overlap the edge of the substrate SB. The upper surface S12 of the second portion P2 may be in contact (physical contact) with the lower surface of the substrate SB. Here, the lower surface of the substrate SB may refer to an exposed surface of the layer or the like in case that a layer or the like is formed on the substrate SB. The upper surface S11 of the first portion P1 may be in contact with the lower surface of the carrier CR, but may be separated from it. The side (L1, corresponding to the side L1 between the first portion P1 and the second portion P2) of the first portion P1 facing the side of the protruded portion of the substrate SB may be in contact with the side of the protruded portion of the substrate SB, but it may be apart. The second portion P2 may be a portion half-etched from the upper surface S11 of the first portion P1 by the first depth d1. The first depth d1 of the second portion P2 that may correspond to the thickness difference t1−t2 of the first portion P1 and the second portion P2 may be in a range of about 5 μm to about 60 μm so as to correspond to the substrate SB and the carrier CR of various sizes. The maximum value of the first depth d1 may be proportional to the thickness of the mask MS. The width w2 of the second portion P2 may be appropriately changed by reflecting a design including a dead space margin (i.e., a region in which the deposition material is allowed to be deposited beyond a design region) and the like.

The mask MS may include the third portion P3 of the third thickness t3. The third portion P3 may define the opening OP, and the second portion P2 may be positioned between the third portion P3 and the first portion P1. The third portion P3 may be a portion further etched from the upper surface S12 of the second portion P2 by the second depth d2. The second depth d2 may be less than or equal to the first depth d1. The second depth d2 may be in a range of about 5 μm to about 40 μm. The second depth d2 may correspond to the thickness difference (t2−t3) between the second portion P2 and the third portion P3. The upper surface S13 of the third portion P3 may be spaced apart from the lower surface of the substrate SB by an interval corresponding to a predetermined or selected interval, for example, the second depth d2. Accordingly, it is possible to prevent the substrate SB from being stamped or damaged by the third portion P3, particularly, the edge ED of the third portion P3. By appropriately setting the distance between the upper surface S13 of the third portion P3 and the lower surface of the substrate SB, it is possible to minimize the shadow region SA1 of the deposited pattern DL while preventing the substrate SB from being stamped. The upper surface S11 of the first portion P1, the upper surface S12 of the second portion P2, and the upper surface S13 of the third portion P3 may include the plane surface that may be perpendicular to the thickness direction of the mask MS and parallel to an x-y plane.

The mask MS may have a stepped structure in which the heights of the first portion P1, the second portion P2, and the third portion P3 gradually decrease toward the opening OP. In such a stepped structure, the mask MS may come into close contact with the substrate SB by the second portion P2, and the third portion P3 may be separated from the substrate SB by a predetermined or selected interval. Accordingly, the substrate SB may be prevented from being damaged by the mask MS and the shadow region SA1 may be reduced.

The third portion P3 of the mask MS may have a tapered shape in which the thickness becomes thinner toward the opening OP. The side surface of the third portion P3 may be inclined at a taper angle θ from the lower surface along the third direction z that is the thickness direction of the mask MS. The taper angle θ may be an acute angle. Accordingly, the width of the opening OP may be smaller toward the upper part (i.e., closer to the substrate SB). To reduce the shadow due to the deposition effective incidence angle, the taper angle θ may be less than about 55 degrees. The edge ED of the third portion P3 may be approximately parallel to the thickness direction of the mask MS without tapering. The thickness t4 of the edge ED may be less than about 20 μm. By setting the thickness of the edge ED in this way, it is possible to secure robust and consistent quality of the edge ED in the length, the width, and depth directions of the third portion P3.

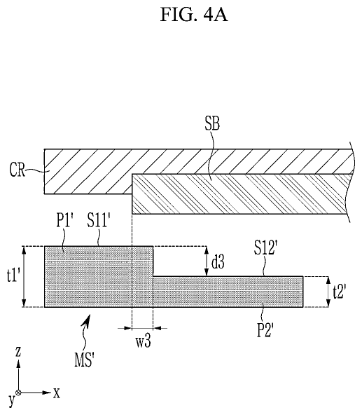

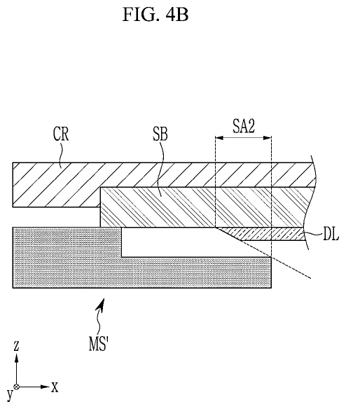

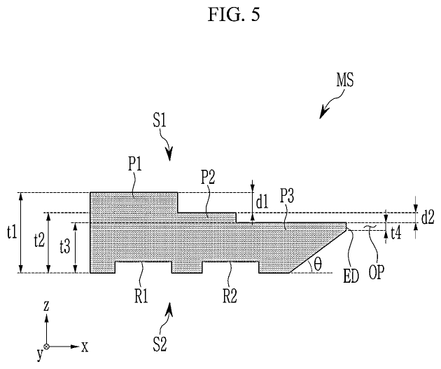

FIG. 4A and FIG. 4B are schematic cross-sectional views of states before and after coupling a deposition mask and a substrate according to a comparative example, respectively.

Referring to FIG. 4A and FIG. 4B, the mask MS′ for the deposition may include a first portion P1′ with a first thickness t1′ and a second portion P2′ with a second thickness t2′. The second portion P2′ may be a half-etched portion with a depth d3 that may correspond to the thickness difference (t1′−t2′) of the first portion P1′ and the second portion P2′. For example, the depth d3 may be in a range of about 40 μm to about 60 μm. In case that the mask MS′ approaches closely, the upper surface S11′ of the first portion P1′ of the mask MS′ and the lower surface of the substrate SB collide or come into close contact due to the interference between the edge of the substrate SB and the mask MS′, thereby damage such as cracks may occur in the substrate SB. Such interference brings restrictions on the adhesion of the mask MS′, and as a result, it is difficult to narrow the gap between the upper surface S12′ of the second portion P2′ and the substrate SB, and the shadow region SA2 may increase.

However, in the mask MS according to the above-described embodiment, by disposing the width w2 and the depth d1 of the second portion P2, which may avoid the interference between the mask MS and the substrate SB, between the first portion P1 and the third portion P3, design freedom by the second portion P2 may be provided to the cross-section of the mask MS and it may be designed to avoid undesirable interference between the mask MS, and the substrate SB and the carrier CR. Therefore, it is possible to prevent the damage of the substrate SB due to the excessive adhesion between the mask MS and the substrate SB, and as shown in FIG. 3B, the shadow region SA1 may be reduced. Accordingly, it is possible to densely dispose the openings OP and maximize the utilization efficiency of the substrate SB.

FIG. 5 is a schematic cross-sectional view of a portion of a deposition mask according to an embodiment.

The mask MS shown in FIG. 5 may correspond to the cross-section taken along line C-C′ in FIG. 2B. Similar to the mask MS shown in FIG. 3A, the mask MS may include the first portion P1, the second portion P2, and the third portion P3 having the first thickness t1, the second thickness t2, and the third thickness t3, respectively. The first portion P1 may be a portion that is not etched, the second portion P2 may be a portion half-etched to a first depth d1, and the third portion P3 may be a portion half-etched to a depth corresponding to the sum of the first depth d1 and the second depth d2. The half etching, which gives the step to the mask MS, may be advantageous in preventing the damage to the substrate SB due to the contact with the substrate SB. However, as the etching depth deepens, a residual stress imbalance in the depth direction of the mask MS for each position intensifies depending on whether the half-etching is performed, so that a phenomenon in which the mask MS is rolled up in the direction of the first surface S1, which is the hard etched surface, may occur. By half-etching the second surface S2 of the mask MS to form at least one groove R1 and R2, the residual stress imbalance may be improved, and the deformation of the mask MS that may occur by half-etching the entire surface of the mask MS may be improved. The grooves R1 and R2 may include a first groove R1 positioned at the first portion P1 and a second groove R2 positioned at the second portion P2 and or the third portion P3, but the number and the position of the grooves R1 and R2 may be varied.

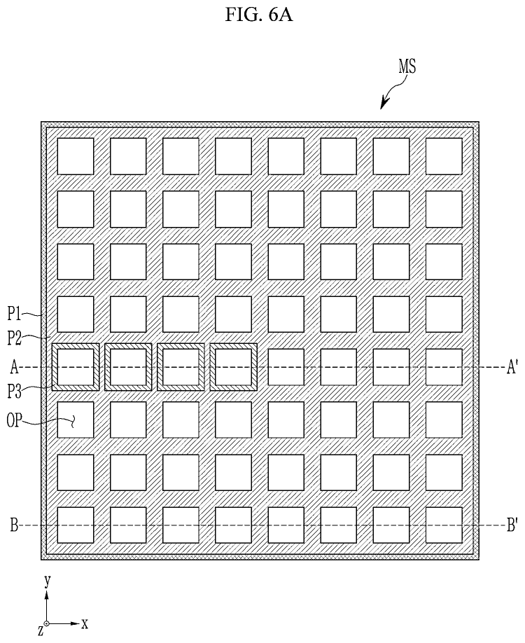

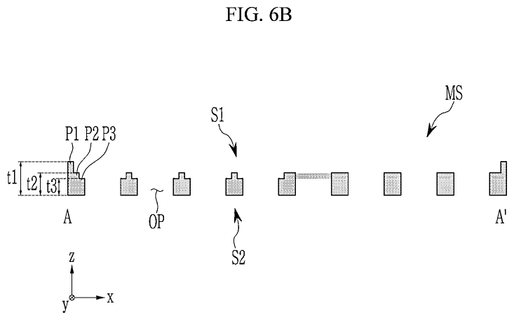

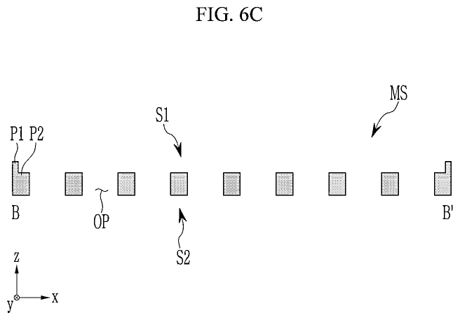

FIG. 6A is a schematic top plan view of a deposition mask according to an embodiment, FIG. 6B is a schematic cross-sectional view taken along line A-A′ of FIG. 6A, and FIG. 6C is a schematic cross-sectional view taken along line B-B′ of FIG. 6A.

Referring to FIG. 6A, FIG. 6B and FIG. 6C, in the mask MS, the shape, composition, and position of the opening OP and the half-etched surface of the multi-layer may be variously changed. For example, only some regions of the mask MS may be used to deposit the pattern on the substrate SB, and for those regions, the third portion P3 with the third thickness t3 may define the opening OP. The mask MS may include the opening OP that is not used to deposit the pattern, such as an opening OP (also called a dummy opening) that may be defined by the second portion P2 with the second thickness t2, but it may be defined by the first portion P1 or the third portion P3.

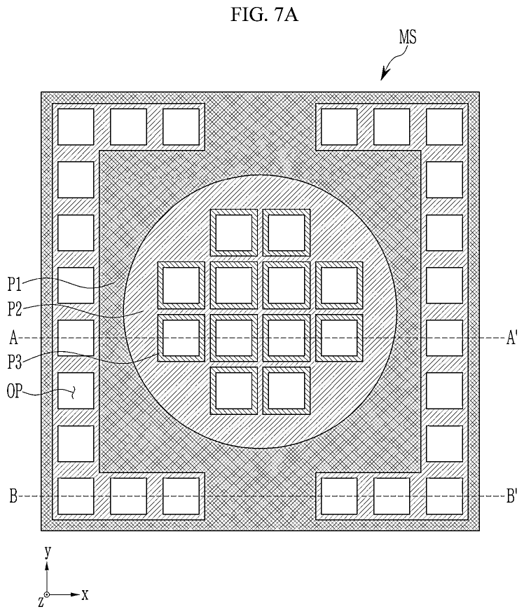

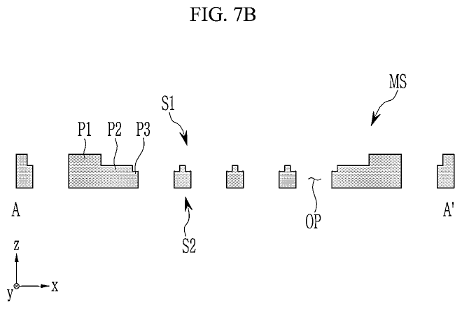

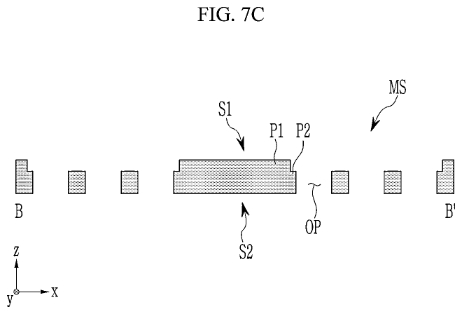

FIG. 7A is a schematic top plan view of a deposition mask according to an embodiment, FIG. 7B is a schematic cross-sectional view taken along line A-A′ of FIG. 7A, and FIG. 7C is a schematic cross-sectional view taken along line B-B′ of FIG. 7A.

Referring to FIG. 7A, FIG. 7B, and FIG. 7C, a first portion P1, a second portion P2, and a third portion P3 of a deposition mask MS may be configured so that the approximate central region of the entire region of the mask MS may be used to deposit the pattern on the substrate SB. In case that the substrate SB is a wafer substrate, the substrate SB may be circular. The first portion P1 may be disposed without overlapping the edge of the substrate SB so as to not interfere with the edge of the substrate SB. In the central portion of the mask MS, the first portion P1 may surround the second portion P2, and the boundary between the first portion P1 and the second portion P2 may be circular in plan view to match the edge of the substrate SB. In this way, the shape, configuration and position of the opening OP of the mask MS and the half-etched surface of the multi-layer may be variously and appropriately designed according to the substrate SB.

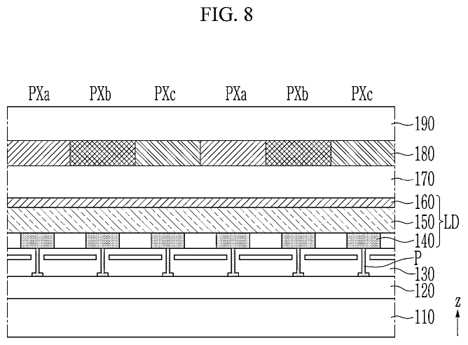

FIG. 8 is a schematic cross-sectional view of a display device according to an embodiment.

Referring to FIG. 8, a display device including a common layer that may be formed using the mask MS for the deposition according to an embodiment is shown. The display device may include a substrate 110 and a light-emitting element LD formed on the substrate 110.

The substrate 110 may be a silicon wafer substrate formed by using a semiconductor process. The substrate 110 may include a semiconductor material, for example a Group IV semiconductor, a Group III-V compound semiconductor, or a Group II-VI compound semiconductor. For example, the Group IV semiconductor may include silicon, germanium, or silicon-germanium. The substrate 110 may be provided as a bulk wafer, an epitaxial layer, a Silicon On Insulator (SOI) layer, or a Semiconductor On Insulator (SeOI) layer.

A driving layer 120 may be positioned on the substrate 110. In the driving layer 120, circuit elements such as transistors, capacitors, and wiring may be disposed. Wiring may include a gate line that transmits a gate voltage, a data line that transmits a data voltage, and the like.

An insulating layer 130 may be positioned on the driving layer 120, and a plug P formed penetrating the insulating layer 130 may be positioned. The insulating layer 130 may include an inorganic insulating material such as a silicon oxide or a silicon nitride. The plug P may be connected to an electrode of a transistor or a conductive layer connected to an electrode of a transistor.

A first electrode 140 of the light-emitting element LD may be positioned on the insulating layer 130. The first electrode 140 may be called a pixel electrode. The first electrode 140 may be individually positioned for each pixel PXa, PXb, and PXc. The first electrode 140 may be connected to the plug P, may be electrically connected to the electrode of the transistor through the plug P, and may receive a driving current for controlling the luminance of the light-emitting element LD. The transistor to which the first electrode 140 is connected may be a driving transistor or a transistor that is electrically connected to the driving transistor. The first electrode 140 may be formed of a reflective conductive material or a semi-transmissive conductive material, or may be formed of a transparent conductive material. The first electrode 140 may include a transparent conductive material such as an indium tin oxide (ITO) or an indium zinc oxide (IZO). The first electrode 140 may include a metal or metal alloy such as lithium (Li), calcium (Ca), aluminum (Al), silver (Ag), magnesium (Mg), and/or gold (Au).

An emission layer 150 of the light-emitting element LD may be positioned on the first electrode 140. On the first electrode 140, in addition to the emission layer 150, a functional layer including at least one of a hole injection layer, a hole transport layer, an electron transport layer, and an electron injection layer may be positioned. The emission layer 150 and the functional layer may be a common layer positioned over the pixels PXa, PXb, and PXc. For example, the emission layer 150 and the functional layer may be continuously formed over the entire substrate 110. The emission layer 150 and the functional layer may be deposited using the aforementioned deposition mask MS.

On the emission layer 150, a second electrode 160 of the light-emitting element LD may be positioned. The second electrode 160 may include a metal such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), and/or lithium (Li). The second electrode 160 may include a transparent conductive oxide such as an indium tin oxide (ITO) or an indium zinc oxide (IZO). The second electrode 160 may be a common layer positioned over pixels PXa, PXb, and PXc. For example, the second electrode 160 may be continuously formed throughout the substrate 110. The second electrode 160 may be deposited using the aforementioned deposition mask MS.

The first electrode 140, the emission layer 150, and the second electrode 160 may constitute a light-emitting element LD that may be an organic light emitting diode. The first electrode 140 may be individually provided for each pixel PXa, PXb, and PXc and may receive a driving current. The second electrode 160 may be commonly provided to the pixels PXa, PXb, and PXc so that a common voltage may be applied. The first electrode 140 may be an anode that is a hole injection electrode, and the second electrode 160 may be a cathode that is an electron injection electrode, or vice versa.

An encapsulation layer 170 may be positioned on the second electrode 160. The encapsulation layer 170 may seal the light-emitting element LD and prevent penetration of moisture or oxygen from the outside. The encapsulation layer 170 may be a thin film encapsulation layer including at least one inorganic layer and at least one organic layer. The inorganic layer may prevent the penetration of moisture and the like, and the organic layer may planarize the surface of the encapsulation layer 170. The inorganic layer may include an inorganic insulating material such as a silicon oxide or a silicon nitride. The organic layer may include organic materials such as an acryl-based resin, a methacrylic resin, a polyisoprene, a vinyl-based resin, an epoxy-based resin, a urethane-based resin, a cellulose-based resin, and/or a perylene-based resin.

A color filter 180 may be positioned on the encapsulation layer 170. The color filter 180 may include a first color filter that transmits light at a first wavelength and absorbs light at remaining wavelengths, a second color filter that transmits light at a second wavelength and absorbs light at remaining wavelengths, and a third color filter that transmits light at a third wavelength and absorbs light at remaining wavelengths. The first color filter, the second color filter and the third color filter may correspond to the first pixel PXa, the second pixel PXb, and the third pixel PXc, respectively. Accordingly, the first pixel PXa, the second pixel PXb, and the third pixel PXc may emit light of the first wavelength, light of the second wavelength, and light of the third wavelength, respectively. One of the first pixel PXa, the second pixel PXb, and the third pixel PXc may be a red pixel, another may be a green pixel, and the other may be a blue pixel.

A cover layer 190 may be positioned on the color filter 180. The cover layer 190 may be formed of a transparent material such as glass or plastic and may be in a form of a substrate.

As the display device including the common layer formed using the mask MS for the deposition according to an embodiment, an OLEDoS structure display device has been described as an example. However, the mask MS for the deposition may be used to deposit layers in various display devices manufactured using glass or plastic substrates.

While this disclosure has been described in connection with what is considered to be practical embodiments, it is to be understood that the disclosure is not limited to the disclosed embodiments. On the contrary, it is intended that various modifications and equivalent arrangements are to be included within the spirit and scope of the disclosure.

What is claimed is:

1. A deposition mask for forming a pattern on a substrate to be deposited, comprising:
a first portion having an upper surface;
a second portion having an upper surface half-etched to a first depth from the upper surface of the first portion; and
a third portion having an upper surface half-etched to a second depth from the upper surface of the second portion, wherein
the third portion defines an opening corresponding to the pattern, and
the upper surface of the third portion includes a plane perpendicular to a thickness direction of the deposition mask.

2. The deposition mask of claim 1, wherein
the upper surface of the first portion and the upper surface of the second portion each include a plane perpendicular to the thickness direction of the deposition mask.

3. The deposition mask of claim 1, wherein
the first portion has a first thickness,
the second portion has a second thickness smaller than the first thickness, and
the third portion has a third thickness smaller than the second thickness.

4. The deposition mask of claim 3, wherein
the second portion is disposed between the first portion and the second portion.

5. The deposition mask of claim 3, wherein
the third portion has a tapered shape in which a thickness is thinner toward the opening.

6. The deposition mask of claim 5, wherein
the third portion has an edge parallel to the thickness direction of the deposition mask.

7. The deposition mask of claim 1, wherein
in case that the substrate and the deposition mask are combined, the upper surface of the second portion is in physical contact with the substrate and the upper surface of the third portion is spaced apart from the substrate.

8. The deposition mask of claim 1, further comprising
at least one groove half-etched from a lower surface of the deposition mask.

9. The deposition mask of claim 8, wherein
the at least one groove includes a first groove disposed in the first portion, and
a second groove disposed in at least one of the second portion and the third portion.

10. The deposition mask of claim 1, wherein
the first portion surrounds the second portion, and
a boundary between the first portion and the second portion is circular in plan view.

11. A deposition mask for forming a pattern on a substrate to be deposited, comprising:
a first portion having a first thickness;
a second portion having a second thickness smaller than the first thickness; and
a third portion having a third thickness smaller than the second thickness,
wherein in case the substrate and the deposition mask are combined, an upper surface of the second portion is in physical contact with a lower surface of the substrate and an upper surface of the third portion is spaced apart from the lower surface of the substrate.

12. The deposition mask of claim 11, wherein
the substrate is fixed to a carrier, and
in case that the substrate and the deposition mask are combined, an upper surface of the first portion is in physical contact with the carrier.

13. The deposition mask of claim 11, wherein
the second portion and the third portion are half-etched at different depths from an upper surface of the first portion of the deposition mask.

14. The deposition mask of claim 13, wherein
the second portion is half-etched from the upper surface of the first portion with a depth in a range of about 5 μm to about 60 μm, and
the third portion is half-etched from the upper surface of the second portion with a depth in a range of about 5 μm to about 40 μm.

15. The deposition mask of claim 13, further comprising:
at least one groove half-etched from a second surface of the deposition mask.

16. The deposition mask of claim 11, wherein
the second portion is disposed between the first portion and the third portion, and
the third portion defines an opening corresponding to the pattern.

17. The deposition mask of claim 16, wherein
the third portion has a tapered shape in which a thickness is thinner toward the opening.

18. The deposition mask of claim 17, wherein
the third portion has an edge parallel to a thickness direction of the deposition mask.

19. The deposition mask of claim 11, further comprising:
an opening defined by the second portion and an opening defined by the third portion.

20. The deposition mask of claim 11, wherein
the first portion surrounds the second portion, and
a boundary between the first portion and the second portion is circular in plan view.
